(19) United States
(12) Patent Application Publication
(10) Pub. No.: US 2020/0358373 A1
(43) Pub. Date: Nov. 12, 2020

(54) TRIBOELECTRICITY BASED CARRIER EXTRACTION IN OPTOELECTRONIC DEVICES AND METHOD

(71) Applicant: KING ABDULLAH UNIVERSITY OF SCIENCE AND TECHNOLOGY, Thuwal (SA)

(72) Inventors: Vincent HSIAO, Thuwal (SA); Siu-Fung LEUNG, Thuwal (SA); Jr-Hau HE, Thuwal (SA)

(21) Appl. No.: 16/960,171

(22) PCT Filed: Oct. 11, 2018
(86) PCT No.: PCT/IB2018/057900

§ 371 Date: Jul. 6, 2020

Related U.S. Application Data
(60) Provisional application No. 62/615,151, filed on Jan. 9, 2018.

(51) Int. Cl. H02N 1/04; H01L 27/142; H01L 51/42

(52) U.S. Cl. CPC H02N 1/04; H01L 31/022466; H01L 51/4206; H01L 27/142

(57) ABSTRACT

A triboelectric photodetector system that includes a triboelectric device configured to generate an electrical current based on a mechanical movement, the triboelectric device having a first compounded layer and a second compounded layer partially separated by a gap; a photodetector, PD, sensor formed on the triboelectric device and configured to transform light energy into electrical energy with a perovskite layer; a first electrical connection that electrically connects a first electrode of the PD sensor to the first compounded layer of the triboelectric device; and a second electrical connection that electrically connects a second electrode of the PD sensor to the second compounded layer of the triboelectric device. The triboelectric device electrically biases the PD sensor to facilitate electrical carrier extraction from the perovskite layer of the PD sensor.

### CROSS-REFERENCE TO RELATED APPLICATIONS

This application claims priority to U.S. Provisional Patent Application No. 62/615,151, filed on Jan. 9, 2018, entitled “AN INNOVATIVE APPROACH FOR CARRIER EXTRACTION IN OPTOELECTRONIC DEVICES USING TRIBOELECTRICITY,” the disclosure of which is incorporated herein by reference in its entirety.

### BACKGROUND

### Technical Field

Embodiments of the subject matter disclosed herein generally relate to an optoelectronic device, and more specifically, to a mechanism that uses triboelectricity for extracting electrical carriers in an optoelectronic device.

### Discussion of the Background

Efficient carrier extraction is desired for obtaining high performance optoelectronic devices, such as solar cells and photodetectors (PDs). Photogenerated carriers in active materials need to be effectively separated and collected by the electrodes in order to contribute to the current, prior to their recombination. Several strategies are widely used for carrier extraction in optoelectronic devices, depending on the material system, device configuration, and the specific application.

In a conventional silicon solar cell, a homogeneous p-n junction is formed by doping and carriers are formed in the junction. As a result, photogenerated carriers are driven toward the contacts and collected by the electrodes with the assistance of the built-in electric field established by the p-n junction. However, doping silicon involves high temperature processes, which increase the energy payback time of the device. Alternatively, heterojunction solar cells, commonly used in dye-sensitized and quantum dot perovskite-based devices, can be prepared using lower temperature processes, but the layering process is time-intensive, which increases the cost.

In the case of PDs, other than separating photogenerated carriers simply by applying an electric bias across a metal-semiconductor-metal architecture, electron and hole transport layers are also employed to efficiently enhance the charge separation and detectivity. For perovskite PDs, [6, 6]-phenyl-C61-butyric acid methyl ester (PCBM) and Spiro-OMeTAD (C₈₁H₆₈N₄O₈) are often used as electron and hole transport layers, respectively. The principle behind photogenerated carrier extraction by electron/hole transport layers is that their work function has a small offset compared with either the conduction or valence band of the photo-absorbing layer. The band alignment between the photo-absorber and electron/hole transport layers enables the extraction of the photogenerated carriers by selectively conducting one type of charge while blocking the transport of the other, thus significantly reducing the dark current and improving the optoelectronic performance.

However, some charge transport layers based on organic materials, such as PCBM and Spiro-OMeTAD, are unstable under light irradiation. The interfaces between the photo-absorber and the electron/hole transport layers must also be handled carefully to prevent defects or cracking. Moreover, the material costs for the charge transport layers are relatively high and require expensive and slow deposition processes. These issues surrounding charge carrier extraction pose a challenge to the fabrication of high-performance, stable, cost-effective, and solution-processed optoelectronic devices for commercial applications.

Thus, there is a need for a new carrier extraction mechanism for optoelectronic devices that is not limited by the above discussed drawbacks.

### SUMMARY

According to an embodiment, there is a triboelectric photodetector system that includes a triboelectric device configured to generate an electrical current based on a mechanical movement, the triboelectric device having a first compounded layer and a second compounded layer partially separated by a gap; a photodetector, PD, sensor formed on the triboelectric device and configured to transform light energy into electrical energy with a perovskite layer; a first electrical connection that electrically connects a first electrode of the PD sensor to the first compounded layer of the triboelectric device; and a second electrical connection that electrically connects a second electrode of the PD sensor to the second compounded layer of the triboelectric device. The triboelectric device electrically biases the PD sensor to facilitate electrical carrier extraction from the perovskite layer of the PD sensor.

According to another embodiment, there is a method for manufacturing a triboelectric photodetector system. The method includes a step of providing a triboelectric device configured to generate an electrical current based on a mechanical movement, the triboelectric device having a first compounded layer and a second compounded layer partially separated by a gap; a step of forming on the triboelectric device a photodetector, PD, sensor, the PD sensor being configured to transform light energy into electrical energy with a perovskite layer; a step of electrically connecting, with a first electrical connection, a first electrode of the PD sensor to the first compounded layer of the triboelectric device; and a step of electrically connecting, with a second electrical connection, a second electrode of the PD sensor to the second compounded layer of the triboelectric device. The triboelectric device electrically biases the PD sensor to facilitate electrical carrier extraction from the perovskite layer of the PD sensor.

According to still another embodiment, there is a method for enhancing carrier extraction in a triboelectric photodetector system. The method includes a step of providing a triboelectric device configured to generate an electrical current based on a mechanical movement, the triboelectric device having a first compounded layer and a second compounded layer partially separated by a gap; a step of providing a photodetector, PD, sensor, the PD sensor being configured to transform light energy into electrical energy with a perovskite layer; and a step of applying a voltage generated by the triboelectric device to the PD sensor to bias the PD sensor to facilitate electrical carrier extraction from the perovskite layer of the PD sensor.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic illustration of a photodetector system having a triboelectric based carrier extraction mechanism;

FIG. 2 is a schematic illustration of another photodetector system having a triboelectric based carrier extraction mechanism;

FIG. 3 illustrates the layer structure of a triboelectric photodetector system;

FIG. 4 illustrates the photoluminescence and the absorption spectrum of a perovskite film that is part of the triboelectric photodetector system;

FIG. 5 is a flowchart of a method for making a triboelectric photodetector system;

FIG. 6 illustrates a triboelectric photodetector system in which the triboelectric device is directly attached to the PD sensor;

FIG. 7 illustrates how the triboelectric photodetector system extracts the carriers;

FIGS. 8A to 8C illustrate how the triboelectric device generates a bias for extracting the carriers from the active layer;

FIGS. 9A and 9B illustrate two biasing configurations of the triboelectric photodetector system;

FIGS. 10A to 10C illustrate various photocurrents of the triboelectric photodetector system relative to a control system and FIG. 10D illustrates the bandgap for the triboelectric photodetector system;

FIGS. 11A to 11D illustrate how a triboelectric photodetector system produces a higher and more constant photocurrent relative to a traditional PD device;

FIG. 12 illustrates the stable current response of the triboelectric photodetector system relative to a traditional PD device;

FIG. 13 illustrates an optoelectronic device that includes a triboelectric photodetector system;

FIG. 14 is a flowchart of a method of making a triboelectric photodetector system; and

FIG. 15 is a flowchart of a method of using a triboelectric photodetector system.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. For simplicity, the following embodiments are discussed with regard to a PD sensor. However, the embodiments are not limited to a PD sensor and one skilled in the art would understand that the same embodiments can be used for any optoelectronic device.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a novel approach for extracting photogenerated carriers from organometallic halide perovskites using triboelectricity is presented. Triboelectricity is a cost-effective and efficient way of converting mechanical movement, such as bending, sliding, and contact, into electricity. Power generation from triboelectric nanogenerators (called herein TENG) requires two materials of different dielectric constants and consistent mechanical motion (continuous or sporadic) to induce equal but opposite charges on the surfaces of the triboelectric device. Since polymer substrates are commonly used in generating triboelectricity, it is possible to utilize these materials in flexible, stretchable, wearable, and self-powered optoelectronic devices.

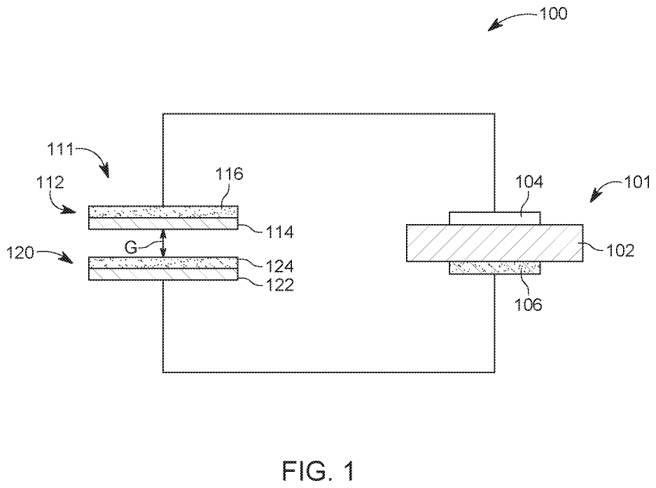

The embodiment illustrated in FIG. 1 shows a triboelectric-actuated PD system 100 that includes a PD sensor 101 and a triboelectric device 111. The PD sensor 101 includes a layer 102 of organometallic halide perovskite sandwiched between a first electrode 104 (e.g., made of gold (Au)) and a second electrode 106 made of another material (e.g., made of indium tin-oxide (ITO)). In one embodiment, a single layer 102 of organometallic halide perovskite is used. As will be discussed later, the specific Au/perovskite/ITO sandwich shown in FIG. 1 is fabricated using low-temperature processes and stable plastic materials, which are flexible and transparent to light.

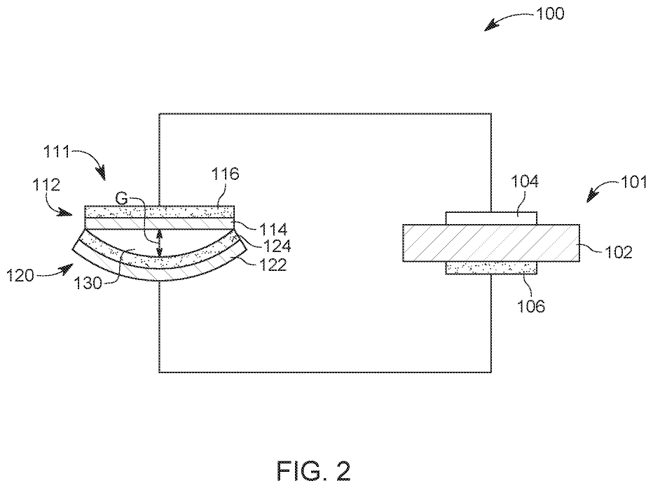

The triboelectric device 111 may have a design that includes a pair of compounded layers 112 and 120, which are partially separated by a gap G. The first compounded layer 112 of the pair includes a first ITO layer 114 coated with a first layer 116 made of polyethylene terephthalate (PET). The second compounded layer 120 of the pair includes a second ITO layer 122 coated with a second PET layer 124. As shown in FIG. 1, the first ITO layer 114 is directly facing the second PET layer 124. Although FIG. 1 shows the first ITO layer 114 completely separated from the second PET layer 124, it is possible, as shown in FIG. 2, that these two layers are partially bonded to each other so that a gap 130 is still present between parts of these two layers. Note that a gap between parts of the two layers needs to be maintained so that one layer is capable of moving relative to the other layer so that triboelectricity can be generated.

In this respect, the triboelectric nanogenerators (TENGs) have demonstrated promising capabilities in harvesting mechanical energy from motion produced from various sources such as humans, wind, and even water droplets. The advantages of TENGs include a high electrical output, simple design and fabrication, and a rich variety of materials that exhibit the triboelectric effect. Different types of sensing systems powered by TENGs are being developed, including those that can detect touch, vibrations, UV light, and molecules using low-cost, highly portable, and widely applicable designs. Moreover, sensors based on TENGs are self-powered (i.e., no external power or storage system is needed) and thus are highly favorable for operating in remote areas as well as outdoor applications.

The triboelectric PD system 100 shown in FIGS. 1 and 2 demonstrate high durability as compared with typical carrier extraction strategies. Due to movement from one of multiple sources (e.g., human movement, wind, sea movement), the plastic triboelectric device 111 generates positive and negative charges that accumulate on the perovskite layer 102 of the PD sensor's electrode surfaces and these charges separate electron/hole pairs generated when the photoactive perovskite layer is illuminated, as discussed later.

The electrical characteristics of the PD sensor 101 were studied under different biases and bending conditions of the triboelectric PD system 100. Notably, it was found that the photocurrent and photo-response time of the PD sensor 101 was enhanced after applying a mechanical force on the triboelectric device 111.

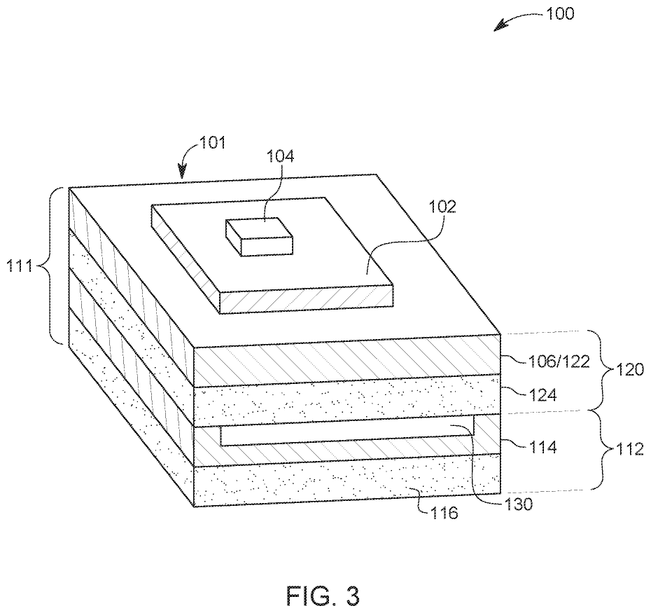

Further, because the triboelectric device 111 is composed of polymer compounded films 112 and 120, the plastic triboelectric device can be integrated into the flexible Au/perovskite/ITO PD sensor 101 as illustrated in FIG. 3. FIG. 3 shows that the ITO electrode 106 in FIG. 1 has been merged with the second ITO layer 122 of the triboelectric device 111 and thus, the perovskite layer 102 is actually formed directly on the second ITO layer 122 of the triboelectric device 111. FIG. 3 shows a gap 130 formed between the second PET layer 124 and the first ITO layer 114 of the triboelectric device 111. The experimental results suggest that triboelectricity can be a novel and cost effective approach for extracting photogenerated carriers in optoelectronic devices, such as solar cells, as well as the possibility of triboelectric-actuated flexible and wearable electronics.

The PD sensor 101 of FIG. 3 may include a thin film 102 of solution-processed (C₄H₉NH₃)₂PbBr₄ perovskite, which is sandwiched between the ITO-coated polyethylene terephthalate (ITO-PET) layer 120 and the gold electrode 104, which is deposited by e-beam evaporation on the perovskite layer 102. A top-view scanning electron microscopy (SEM) image of the perovskite film 102 reveals the presence of voids between the crystalline boundaries. The film 102 also features uneven crystal domains approximately 100 nm in size. A cross-sectional SEM image of the material suggests a multi-layered, two dimensional network, inside a 1 μm thick perovskite thin film 102, most likely due to the 2D perovskite structure of the C₄H₉NH₃Br precursor.

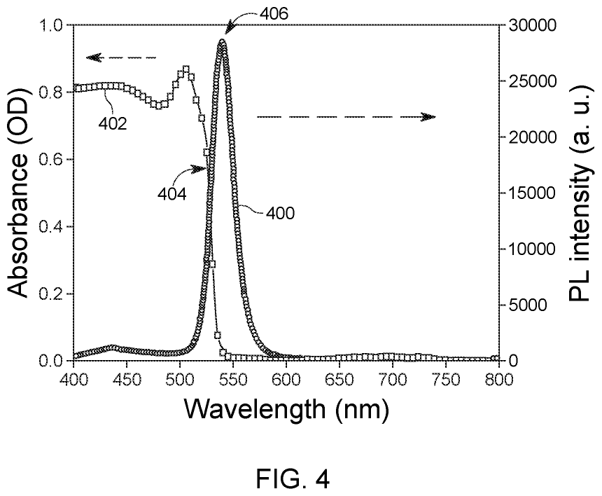

FIG. 4 shows the photoluminescence (PL) 400 and the absorption spectrum 402 of the perovskite film 102, which exhibits a sharp absorption edge 404 at 530 nm (2.3 eV) and a PL peak 406 located at 548 nm.

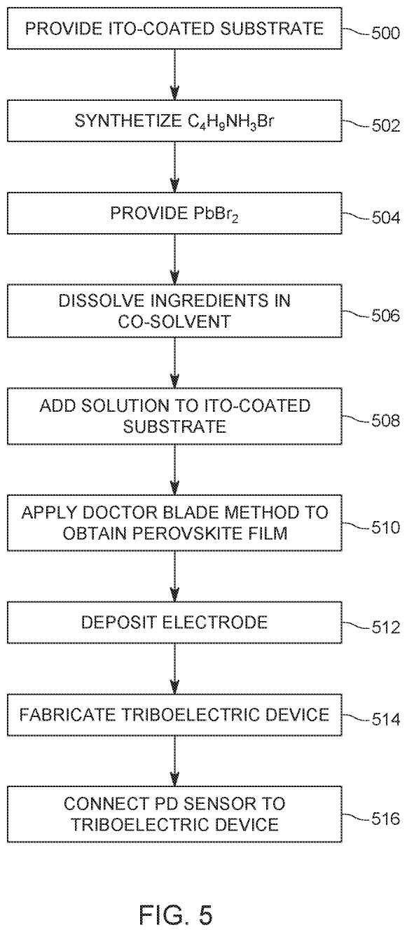

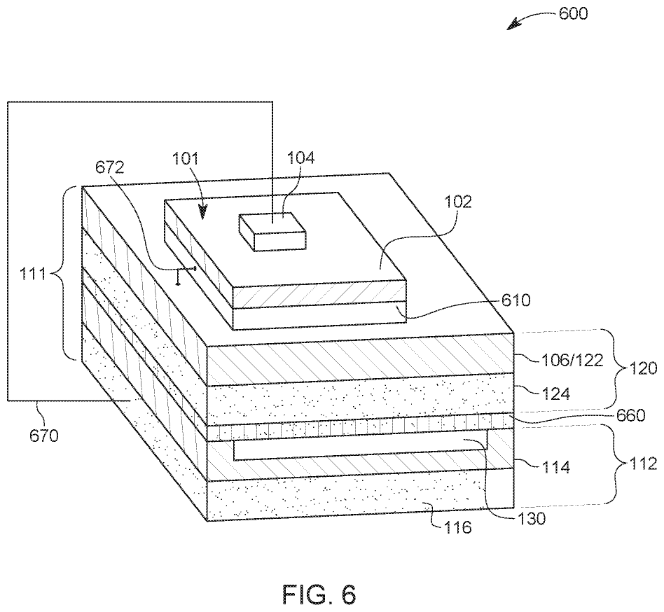

A method for forming a triboelectric PD system (for example, the system 600 as illustrated in FIG. 6) is now discussed with regard to FIG. 5. In step 500, an ITO-coated PET substrate 610 has been provided. For example, this substrate is commercially available. Otherwise, the substrate may be manufactured. Next, the perovskite layer 102 was prepared using a modified co-solvent assisted method, as reported, for example, in Dou 2015. In step 502, the C₄H₉NH₃Br was synthesized following a recipe in Dou 2015 and in step 504 a solution of PbBr₂ was provided. These reagents were dissolved in step 506 in a co-solvent (e.g., 4 ml), containing half of the volume (e.g., 2 ml) dimethylformamide (anhydrous, 99.8%) and the other half of the volume (e.g., 2 ml) chlorobenzene (anhydrous, 99.8%). In step 508, part (e.g., 40 μL) of this mixed solution was added onto the ITO-coated PET substrate 610 provided in step 500, featuring, for example, a 25 Ω/sq surface resistivity. A doctor blading method was applied in step 510 to create the perovskite thin film 102 while the substrate 610 was heated at 70° C. on a hot plate for 1 h. An electrode 104 (for example, Au) is deposited in step 512 on the perovskite thin film 102. The electrode may have a 40 nm thickness. The electrode 104 may be deposited by sputtering, as the top electrode of the perovskite thin film 102.

Then, the triboelectric device 111 was fabricated in step 514 using two (e.g., 10 mm×10 mm) ITO-coated PET substrates 112 and 120, as illustrated in FIG. 6. The triboelectric device 111, which is powered by bending, was fabricated using a PTFE layer 660 inserted between the two ITO coated PET compounded layers 112 and 120 of the combined device so that the gap 130 is formed between the PTFE layer 660 and the first ITO layer 114. The PTFE layer can be part of the first or second compounded layers 112 or 120. In one application, the PD sensor 101 is formed (or attached) directly to the triboelectric device 111, as shown in FIG. 6. The Au/perovskite/ITO PD sensor 101 is then electrically connected in step 516 to both triboelectric compounded layers 112 and 120, for example, by copper wires 670 and 672. The first wire 670 connects the first PET layer 116 to the first electrode 104 and the second wire 672 connects the substrate 610 to the first ITO layer 106. In one application, it is possible to connect the copper wires to these layers by using 3M transparent vinyl tape.

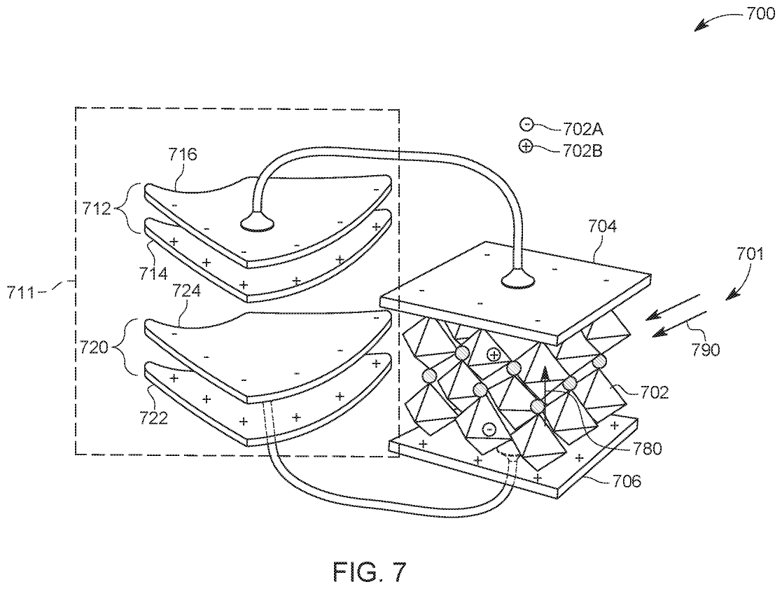

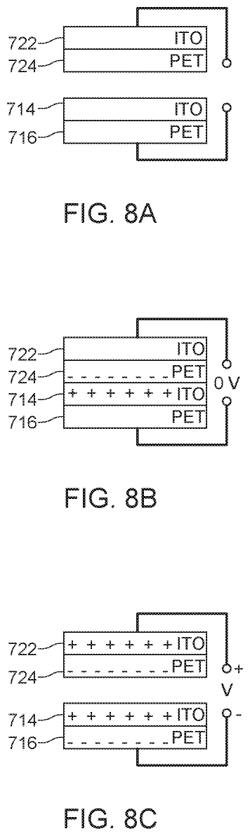

The novel carrier extraction properties of the triboelectric-assisted perovskite PD system 100 are now explained with regard to FIGS. 7 to 8C. As previously discussed with regard to the embodiment of FIGS. 1, 2, 3, and 6, a triboelectric device, element 711 in FIG. 7, includes two ITO-coated PET layers 712 and 720 connected to the Au electrode 704 and the ITO electrode 706 of the PD sensor 701. FIG. 8A shows the initial position of the two compounded layers 712 and 720 and also the fact that there are no electrical charges on either of these layers.

When the triboelectric device 711 is tapped, bringing the surfaces of the second PET layer 724 and the first ITO layer 714 in contact with each other, as illustrated in FIG. 8B, positive and negative charges (illustrated in the figures by “+” and “−”, respectively) are generated due to the triboelectric effect and initially accumulate on the second PET layer 724 and the first ITO layer 714. When the first and second compounded layers 712 and 720 are separated as illustrated in FIG. 8C (as the tap has elapsed), an amount of charges of opposite sign is generated on the first PET layer 716 and the second ITO layer 722, relative to the second PET layer 724 and the first ITO layer 714, respectively.

These electrical charges spread to the first electrode 704 and the second electrode 706 of the PD sensor 701, as illustrated in FIG. 7. As a result of these electrical charges, an electric field 780 is established across the perovskite layer 702. When the perovskite layer 702 is illuminated with light 790, photocarriers 702A and 702B are generated (i.e., electrons and holes) inside the perovskite layer 702, and the triboelectric-generated electric field 780 separates the electron-hole pairs and prevents carrier recombination inside the active layer 702.

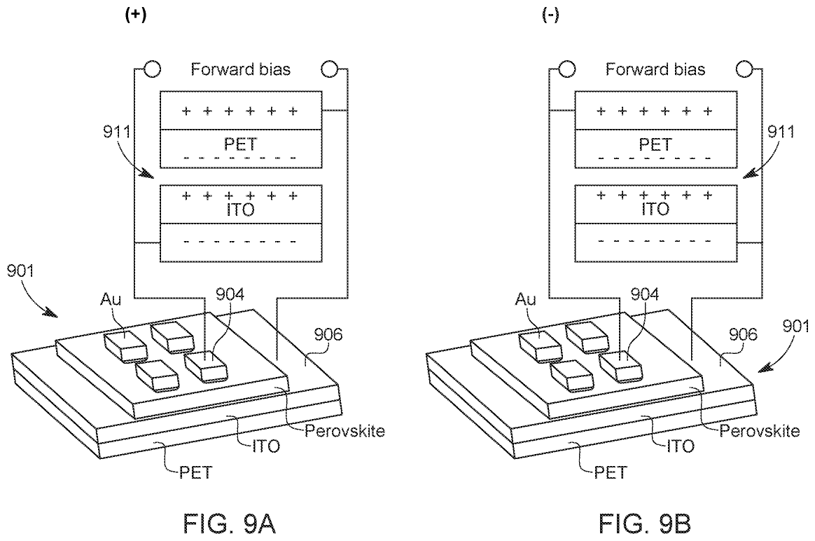

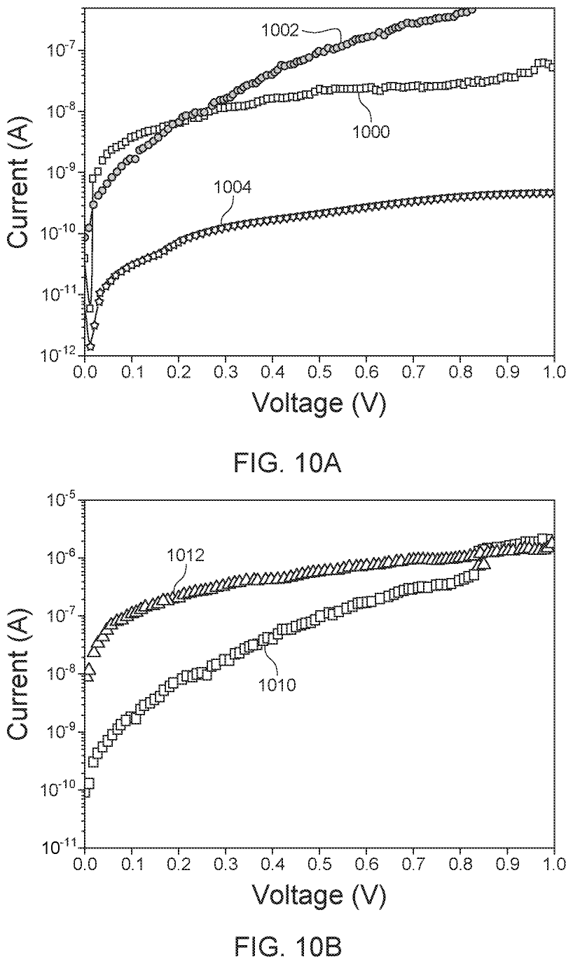

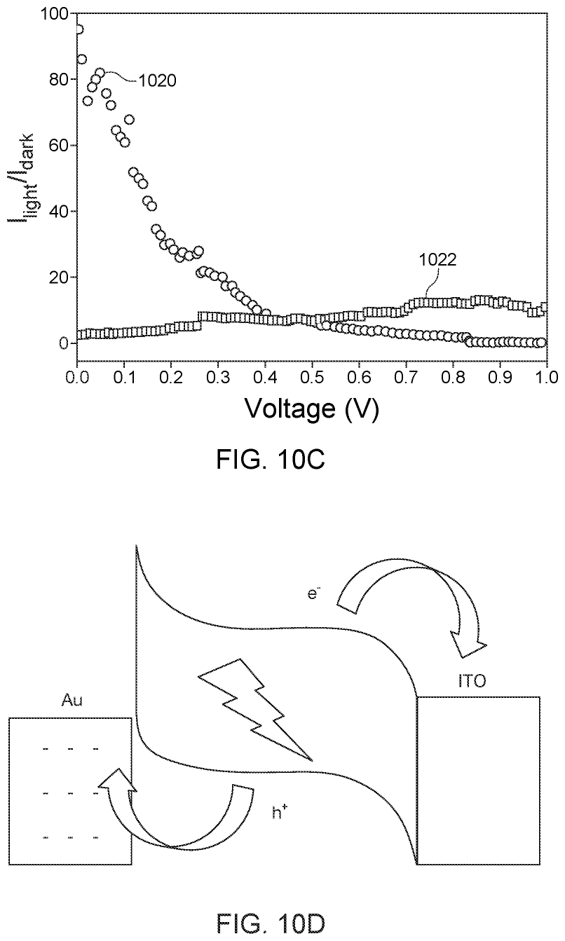

To characterize the properties of this new carrier extraction mechanism, the triboelectric-actuated PD system 100 has been configured as shown in FIGS. 9A and 9B and the current-voltage (I-V) curves of the Au/perovskite/ITO PD sensor 901 biased by the triboelectric device 911 have been measured as illustrated in FIGS. 10A to 10C. All the electrical connections between the triboelectric device 911 and the perovskite PD sensor 901 were in parallel. The (+) symbol at the top of FIG. 9A indicates that the positive charges (+) were connected to the ITO electrode 906 of the PD sensor 901 while the (−) symbol at the top of FIG. 9B indicates that the negative charges (−) were connected to the ITO electrode 906. All I-V curves in FIGS. 10A and 10B were obtained under the forward bias condition. By finger tapping the ITO-PET substrates, triboelectric charges are generated at the interface of these materials. The continuous contact and separation of the top and bottom ITO-PET layers (as illustrated in FIGS. 8A to 8C) results in the accumulation of triboelectric charges of opposite signs at the contact surface, as shown in FIGS. 8B and 8C, which induce a constant external voltage on the perovskite layer.

FIG. 10A compares the I-V curves (dark current) of the perovskite PD with or without a triboelectric-induced bias and under different electric connections. Without the use of electron and hole transport layers, the I-V behavior of the perovskite PD sensor could be considered a Schottky junction naturally formed at the interface between the electrodes and the semiconducting perovskite, as illustrated in FIG. 10D. The application of a forward bias (V_{for}) lowers the Schottky barrier height and facilitates the charge carriers moving to the electrodes, increasing the current with the applied voltage, as shown in FIG. 10A for the control curve 1000. The I-V curve 1002 measured when the perovskite PD sensor is biased with (+) triboelectric-generated charges shows improved performance compared to the control curve 1000, when the applied voltage is higher than 0.3 V. In contrast, the application of the (−) triboelectric connection decreased the current 1004 by 2 orders of magnitude, hurting the performance of the triboelectric PD system.

The enhanced I-V characteristics 1002 from the (+) triboelectric-assisted PD system can be explained by the energy band alignment of the Au/perovskite/ITO PD sensor 701. Because the work function of the Au electrode 704 is higher than the ITO electrode 706, electrons are facilitated to flow into the ITO electrode 706 under V_{for}. The application of the (+) triboelectric configuration (see FIG. 9A) results in positive and negative charges accumulating at the ITO and gold electrodes, respectively. The accumulated charges, which serve the same role as electron/hole transport layers in a typical perovskite PD sensor, help separate the photo-generated electron/hole pairs 702A and 702B and contribute to the photocurrent under the forward-biased condition. In contrast, the application of the (−) triboelectric configuration (see FIG. 9B) results in negative surface charges on the ITO electrode and positive charges on the Au electrode. The accumulated charges, which could be considered as the reverse biased condition, prevents photo-generated electron/hole pairs 702A and 702B from separating in the perovskite layer 702, and thus, a lower photocurrent 1004 was observed under the application of (−) triboelectric-generated charges.

Note that before illumination, the dark current (I_{dark}) 1002 from the (+) triboelectric-biased perovskite PD sensor at zero bias is almost 10 times larger than that measured from the control current 1000, as shown in FIG. 10A. The I_{dark} 1002 from the (+) triboelectric-biased perovskite device is also slightly higher than the control 1000 when applying the forward bias.

FIG. 10B shows the I-V curves 1010 and 1012 measured for the (+) triboelectric-biased device under dark and illuminated conditions, respectively. Interestingly, the I_{light} 1012 at zero bias was almost 100-times larger than I_{dark} 1010. The generated charges from the application of the (+) triboelectric condition create an electric field that promotes a photocurrent without the external forward bias. However, under illumination, the I_{light} measured from the (−) triboelectric-biased device was the same as I_{dark}, either with or without an external forward bias. This suggests that the application of the (−) triboelectric connection turns off the perovskite PD sensor.

To evaluate the effect of triboelectrics on the perovskite PD sensor under an external forward voltage, the value of I_{light}/I_{dark} for the triboelectric-biased perovskite PD system and a control device were calculated, as shown in FIG. 10C. The (+) triboelectric-biased device had the largest value 1020 of I_{light}/I_{dark}, which can be explained by the (+) triboelectric condition providing additional built-in potential to lower the Schottky barrier height and facilitate charge separation. However, the I_{light}/I_{dark} value decreases with increasing the applied voltage, which is in contrast with the control device. For the control device, the ability to separate charges increases with an increase of the external voltage, in which case I_{light}/I_{dark} 1022 increases with the applied voltage. For the case of the (+) triboelectric-biased perovskite PD system, an external bias reduces the triboelectric effect, so that when V_{for} is larger than 0.5 V, the value of I_{light}/I_{dark} 1022 of the control device was actually larger than the (+) current ratio 1020 for the triboelectric-biased PD system. These results demonstrate that the application of triboelectrics is useful in non-biased optoelectronics. FIG. 10D shows a schematic of the band alignment of the (+) triboelectric-biased Au/perovskite/ITO PD system. Under illumination, the lower Schottky barrier makes the photogenerated holes migrate to the Au/perovskite interface, leaving behind the unpaired electrons in the perovskite/ITO interface and contributing to the photocurrent. The generation of surface charges on the Au and ITO electrodes results in more efficient photocurrent extraction and improved photoresponse.

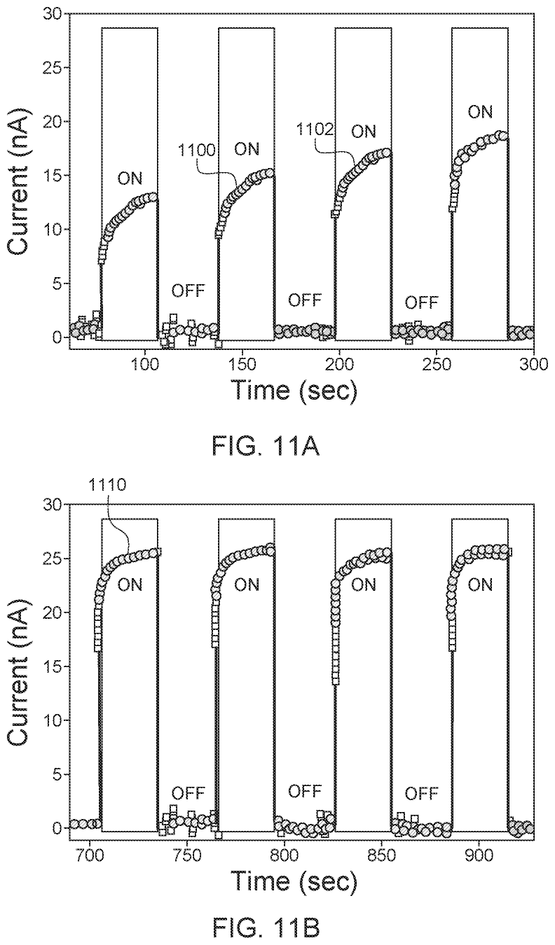

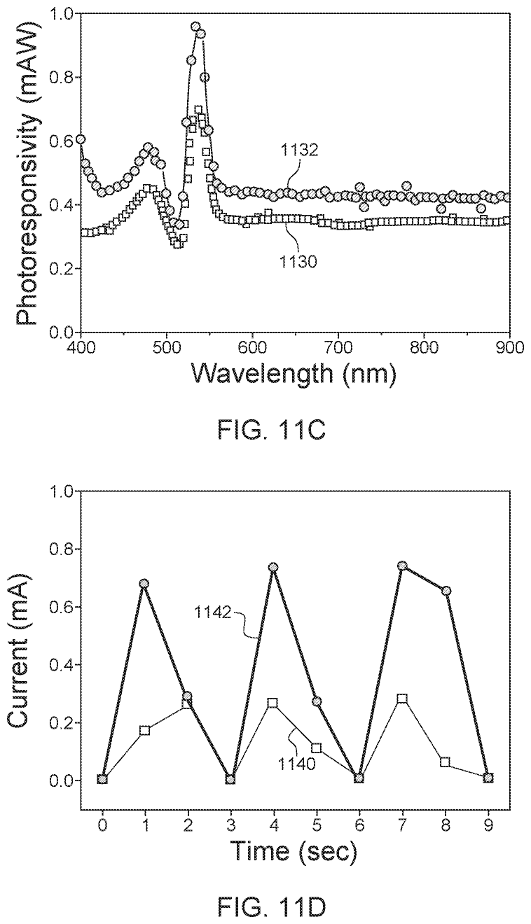

The transient photoresponse of a control perovskite PD system under white light illumination (10 mW cm⁻²) is shown in FIG. 11A. The photocurrent 1100 is switched ON and OFF by periodically blocking the white light source at zero bias. The resulting photocurrent increases slowly during illumination without saturating and rapidly drops to zero when the light is removed (during the OFF period). When the light is turned on again, the unsaturated photocurrent 1102 is again observed, but it becomes higher than the value obtained from the previous pulse 1100.

FIG. 11B shows the photoresponse of the (+) triboelectric-biased perovskite PD system 100 under the same intensity of white light illumination. The photocurrent 1110 saturates more rapidly and features a higher photocurrent compared to the control device (see current 1100) due to the generation of positive and negative surface charges by the triboelectric bias. The triboelectric-generated positive/negative charges prevent the photo-generated charge carriers inside the perovskite from becoming trapped and recombining, thus facilitating carrier drift to the electrodes.

The spectral response of the Au/perovskite/ITO PD system 100 was characterized, as illustrated in FIG. 110, before and after triboelectric biasing. Before applying triboelectric charges, at zero external bias, the photocurrent spectral response (i.e., photoresponsivity) 1130 of the PD system is comprised of a strong and narrow exciton band at 535 nm with a full width at half maximum of 20 nm and a broad photoresponse region correlated to the band-to-band transitions. The strong and narrow spectral response matches the absorption band edge of the perovskite layer. Under illumination, electron and hole carriers are generated and the built-in potential created from the Schottky junction interface helps to separate the photogenerated carriers toward their respective electrodes. Compared to the control PD device, the photocurrent response 1132 measured from the triboelectric-biased PD system 100 increases in the entire spectral range (400-900 nm). The photocurrent response 1132 observed from the triboelectric-biased PD system 100 shows no substantial variation in term of spectral position and width. These behaviors indicate that the assistance of triboelectricity is correlated with the increased photocurrent spectral response.

Without electron/hole transport layers in a perovskite PD system, the photocurrent is normally unstable due to charge recombination inside the active material. It is possible to evaluate the stability of the PD system by continuously switching the light source on and off as the photocurrent is measured. Under these conditions, a higher photocurrent suggests improvement in the charge separation of the electron/hole pairs. FIG. 11D shows (1) the transient photocurrent response 1140 of the PD system without (+) triboelectric-biasing and (2) the transient photocurrent response 1142 of the same system with (+) triboelectric biasing. Both currents were measured under an optical chopping frequency of 3 Hz using a 532 nm and 100 mW laser as the probing light source. The photocurrent 1142 measured from the triboelectric-biased PD system is almost three times larger compared to the response 1140 without triboelectric treatment. A comparison of the transient photocurrent at different optical chopping frequencies for the PD system with/without triboelectric charges shows that triboelectric biasing can effectively improve the photodetection performance of the perovskite PD in terms of photocurrent and stability.

One of the advantages of utilizing triboelectricity for carrier extraction in a PD system is the compatibility of the plastic-fabricated triboelectric device 111 with flexible and wearable electronic devices 101. Existing perovskite PD sensors exhibit fairly stable flexible perovskite PDs based on a layered design that utilizes electron/hole transport layers. However, the fabrication of the electron/hole layers, as previously discussed, involves costly processes, making it difficult to produce a flexible perovskite PD system that is stable under various bending conditions.

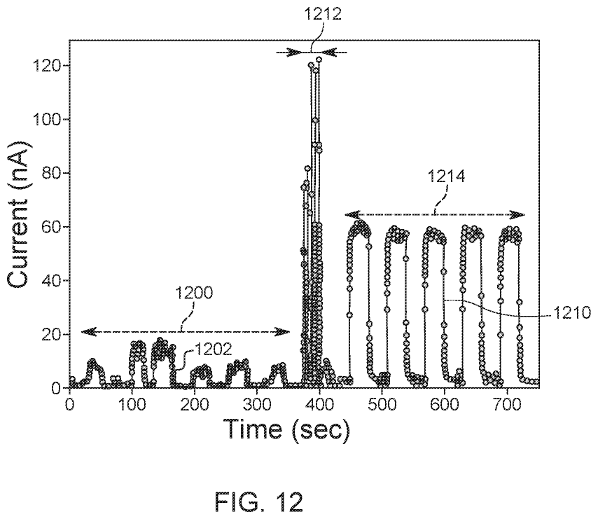

The flexible Au/perovskite/ITO PD system discussed in the previous embodiments (e.g., 100, 700 or 900) can bend with a bending radius of 2 cm. Without the assistance of an external voltage or triboelectric biasing, the photoresponse 1202 of the system is not stable under alternating light illumination, as illustrated in FIG. 12 for region 1200. However, a reproducible and stable photocurrent 1210 is observed for the triboelectric PD system 100 when biased by the triboelectric device 111. FIG. 12 shows a time period 1212 when the triboelectric current is applied to the PD sensor and then a time period 1214 of ON/OFF switching of the system. The triboelectric device 111 effectively replaces the role of (1) an external voltage source and (2) electron/hole transport layers.

According to one or more embodiments discussed above, a novel approach for extracting photogenerated carriers in optoelectronic devices has been introduced by using a triboelectric device. Without the need for electron/hole transport layers, the perovskite PD system constructed using a 2D perovskite layer sandwiched between Au and ITO-PET electrodes can generate a high and stable photoresponse when assisted by triboelectricity, which produces an electric field through the mechanical motion of contact and separation between two ITO-coated PET substrates. Without the use of electron/hole transport layers or external bias, it was observed that bending the perovskite layer without the charges supplied by the triboelectric device results in unstable and low photocurrent measurements. However, by using the triboelectric device, the resulting voltage helps facilitate stable and reproducible photocurrents through improved charge carrier separation.

Moreover, by integrating a flexible triboelectric device with the flexible perovskite PD sensor as illustrated in FIGS. 3 and 6, the triboelectric PD system can be bended to modulate the resulting photoresponse. The efficiency of using triboelectricity is lower than the traditional methods of charge carrier separation, however, the present system is advantageous because of the low-cost fabrication, enhanced stability, and self-powered nature, which suggests that further developments may enable triboelectricity to eventually replace organic charge transport layers. These embodiments demonstrate the potential of the simple and durable triboelectric device design illustrated in FIGS. 1, 2, 3, 7, and 9 for efficient carrier extraction for enhanced performance in flexible optoelectronic devices.

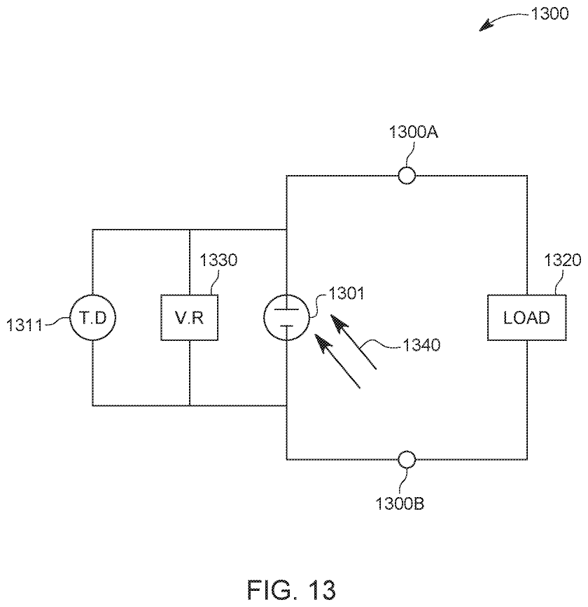

The triboelectric PD system discussed in the previous embodiments may be implemented in any existing optoelectronic device as now discussed with regard to FIG. 13. FIG. 13 shows an optoelectronic device 1300 (for example, a solar cell, but any other optoelectronic device may be used) that includes a PD sensor 1301 having a structure similar to the PD sensor 101, 701 or 901. The PD sensor 1301 is electrically connected to the triboelectric device 1311, which has a similar structure to the triboelectric device 111, 711 or 911. A voltage regulator 1330 may be connected in parallel to the PD sensor 1301 and triboelectric device 1311, for regulating a voltage generated by the triboelectric device. The voltage regulator 1330 may include a diode, and/or resistor, and/or transistor or other semiconductor devices.

The optoelectronic device 1300 has two output terminals 1300A and 13008, which may be connected to a load 1320. If the optoelectronic device 1300 is a photo cell, the energy produced by the PD sensor 1301, when biased by the triboelectric device 1311, is available for the load 1320 (e.g., a device that uses electrical power) to be consumed. If the optoelectronic device 1300 is a photodetector used in optical communications, than load 1320 may be an electronic circuit that measures a change in the voltage or current generated by the PD sensor 1301, when illuminated by light 1340. Other functions may be performed by the load 1320 depending on the purpose of the optoelectronic device 1300.

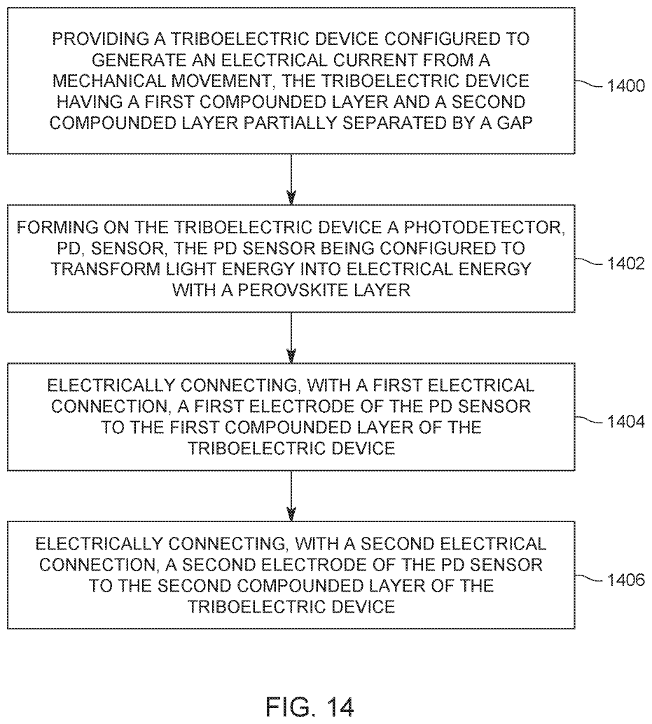

A method for manufacturing a triboelectric photodetector system 100, 600 is now discussed with regard to FIG. 14. The method includes a step 1400 of providing a triboelectric device 111 configured to generate an electrical current from a mechanical movement, the triboelectric device 111 having a first compounded layer 112 and a second compounded layer 120 partially separated by a gap 130, a step 1402 of forming, on the triboelectric device 111, a PD sensor 101, the PD sensor being configured to transform light energy into electrical energy with a perovskite layer 102, a step 1404 of electrically connecting, with a first electrical connection 670, a first electrode 104 of the PD sensor 101 to the first compounded layer 112 of the triboelectric device 111, and step 1406 of electrically connecting, with a second electrical connection 672, a second electrode 106 of the PD sensor 101 to the second compounded layer 120 of the triboelectric device 111, where the triboelectric device 111 electrically biases the PD sensor 101 to facilitate electrical carrier extraction from the perovskite layer 102 of the PD sensor 101.

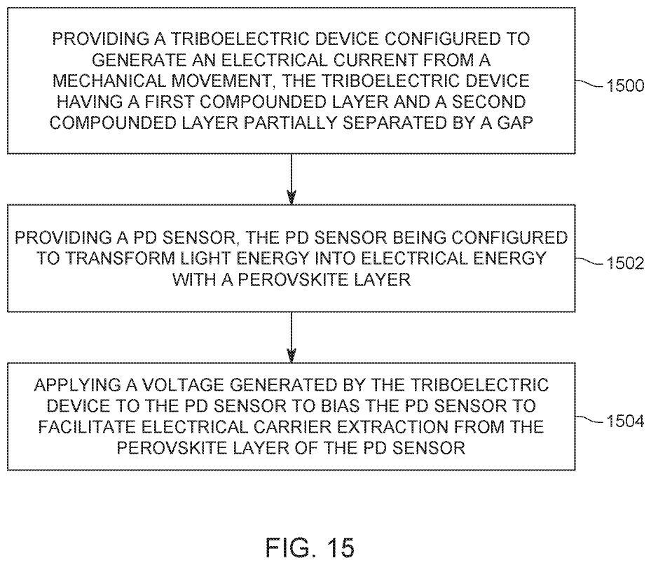

A method for enhancing carrier extraction in a triboelectric photodetector system 100 or 600 is now discussed with regard to FIG. 15. The method includes a step 1500 of providing a triboelectric device 111 configured to generate an electrical current from a mechanical movement, the triboelectric device 111 having a first compounded layer 112 and a second compounded layer 120 partially separated by a gap 130, a step 1502 of providing 1502 a photodetector, PD, sensor 101, the PD sensor being configured to transform light energy into electrical energy with a perovskite layer 102, and a step 1504 of applying a voltage generated by the triboelectric device 111 to the PD sensor to bias the PD sensor 101 to facilitate electrical carrier extraction from the perovskite layer 102 of the PD sensor 101.

The disclosed embodiments provide methods and mechanisms for extracting electrical charge carries in a triboelectric PD system. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

L. Dou, A. B. Wong, Y. Yu, M. Lai, N. Kornienko, S. W. Eaton, A. Fu, C. G. Bischak, J. Ma, T. Ding, N. S. Ginsberg, L.-W. Wang, A. P. Alivisatos, P. Yang, Science 2015, 349, 1518.

1. A triboelectric photodetector system comprising:
a triboelectric device configured to generate an electrical current based on a mechanical movement, the triboelectric device having a first compounded layer and a second compounded layer partially separated by a gap;
a photodetector, PD, sensor formed on the triboelectric device and configured to transform light energy into electrical energy with a perovskite layer;
a first electrical connection that electrically connects a first electrode of the PD sensor to the first compounded layer of the triboelectric device; and
a second electrical connection that electrically connects a second electrode of the PD sensor to the second compounded layer of the triboelectric device,
wherein the triboelectric device electrically biases the PD sensor to facilitate electrical carrier extraction from the perovskite layer of the PD sensor.

2. The system of claim 1, wherein parts of the first compounded layer and the second compounded layer of the triboelectric device are bonded to each other.

3. The system of claim 1, wherein the perovskite layer includes (C₄H₉NH₃)₂PbBr₄, the first electrode includes gold, and the second electrode includes indium tin-oxide (ITO).

4. The system of claim 3, wherein the first compounded layer includes a first layer of ITO, a first layer of polyethylene terephthalate (PET), and a layer of polytetrafluoroethylene (PTFE).

5. The system of claim 4, wherein the second compounded layer includes a second layer of ITO and a second layer of PET.

6. The system of claim 5, wherein the gap is formed directly between the PTFE layer of the first compounded layer and the second ITO layer of the second compounded layer.

7. The system of claim 1, wherein the PD sensor is directly formed on the triboelectric device.

8. The system of claim 1, wherein the PD sensor is a solar cell.

9. The system of claim 1, wherein the PD sensor is part of an optical communication device.

10. The system of claim 1, wherein both the PD sensor and the triboelectric device are flexible and the triboelectric device generates electrical charges when bent.

11. A method for manufacturing a triboelectric photodetector system, the method comprising:
providing a triboelectric device configured to generate an electrical current based on a mechanical movement, the triboelectric device having a first compounded layer and a second compounded layer partially separated by a gap;
forming on the triboelectric device a photodetector, PD, sensor, the PD sensor being configured to transform light energy into electrical energy with a perovskite layer;
electrically connecting, with a first electrical connection, a first electrode of the PD sensor to the first compounded layer of the triboelectric device; and
electrically connecting, with a second electrical connection, a second electrode of the PD sensor to the second compounded layer of the triboelectric device,
wherein the triboelectric device electrically biases the PD sensor to facilitate electrical carrier extraction from the perovskite layer of the PD sensor.

12. The method of claim 11, further comprising:
bonding parts of the first compounded layer to the second compounded layer of the triboelectric device while maintaining the gap between other parts.

13. The method of claim 11, further comprising:
synthesizing the perovskite layer by dissolving C₄H₉NH₃Br and PbBr₂ reagents in a co-solvent that includes dimethylformamide and chlorobenzene to obtain a mixed solution; and
adding the mixed solution to a substrate while the substrate is heated for a given time, to form a (C₄H₉NH₃)₂PbBr₄ layer, which is the prevoskite layer of the PD sensor.

14. The method of claim 13, further comprising:
forming the PD sensor directly onto the triboelectric device.

15. The method of claim 11, wherein the first compounded layer includes a first layer of ITO, a first layer of polyethylene terephthalate (PET), and a layer of polytetrafluoroethylene (PTFE).

16. The method of claim 15, wherein the second compounded layer includes a second layer of ITO and a second layer of PET.

17. The method of claim 16, further comprising:
forming the gap directly between the PTFE layer of the first compounded layer and the second ITO layer of the second compounded layer.

18. The method of claim 11, wherein the PD sensor is a solar cell or a part of an optical communication device.

19. The method of claim 11, further comprising:
bending the triboelectric device to generate electrical charges,
wherein both the PD sensor and the triboelectric device are flexible.

20. A method for enhancing carrier extraction in a triboelectric photodetector system, the method comprising:
providing a triboelectric device configured to generate an electrical current based on a mechanical movement, the triboelectric device having a first compounded layer and a second compounded layer partially separated by a gap;
providing a photodetector, PD, sensor, the PD sensor being configured to transform light energy into electrical energy with a perovskite layer; and
applying a voltage generated by the triboelectric device to the PD sensor to bias the PD sensor to facilitate electrical carrier extraction from the perovskite layer of the PD sensor.
